(19) United States
(12) Patent Application Publication
(10) Pub. No.: US 2017/0175247 A1
(43) Pub. Date: Jun. 22, 2017

(54) SPUTTERING SOURCE ARRANGEMENT, SPUTTERING SYSTEM AND METHOD OF MANUFACTURING METAL-COATED PLATE-SHAPED SUBSTRATES

(71) Applicant: Evatec AG, Trubbach (CH)

(72) Inventor: Jurgen Weichart, Balzers (LI)

(21) Appl. No.: 15/039,518

(22) PCT Filed: Dec. 3, 2014
(86) PCT No.: PCT/EP2014/076415

§ 371 Date: May 26, 2016

Related U.S. Application Data
(60) Provisional application No. 61/911,630, filed on Dec. 4, 2013.

(51) Int. Cl. C23C 14/04; C23C 14/34; H01L 21/768; C23C 14/16; H01L 21/285; H01J 37/34; C23C 14/35

(52) U.S. Cl. CPC C23C 14/046; H01J 37/3405; H01J 37/3423; H01J 37/3417; H01J 37/3438; H01J 37/3497; H01J 37/3467; C23C 14/3485; C23C 14/352; C23C 14/3407; C23C 14/165; C23C 14/3492; H01L 21/2855; H01L 21/76873; H01L 21/76898

(57) ABSTRACT

For coating substrates (S) having along their surfaces to be coated high aspect ratio vias, a sputtering system has a sputtering source arrangement, which includes a first DC pulse operated magnetron sub-source (1203) and a second frame-shaped magnetron sub-source (1213) which latter is arranged, in the system, between the substrate (S) and the first magnetron sub-source (1203). The second magnetron sub-source (1213) may be operated in DC, pulsed DC, thereby also HIPIMS mode. The first magnetron sub-source (1203) is advantageously also operated in HIPIMS mode. The substrate (S) is biased by an Rf power source (1253).

The present invention relates to the art of depositing layers by physical vapor deposition, commonly known as PVD. One type of PVD is sputter deposition. Thereby, one type of the sputter deposition technology is so-called “magnetron sputtering”. Under sub-atmospheric conditions a material plate, called target, is bombarded by ions exhibiting an energy >>1 eV. Material is sputtered off the target at its sputtering surface, for subsequent deposition on a substrate. Magnetron sputtering relies on a glow plasma discharge which is generated by an electric field between the target, acting as a cathode, and an anode which is often realized by grounded parts of the vacuum recipient wherein the magnetron sputtering process is performed. The plasma is localized and retained close to the sputtering surface of the target by means of a magnet arrangement generating upon the sputtering surface a closed loop of tunnel-shaped magnetic field. This magnetic field forces the electrons of the plasma in a closed loop. Therefore, the magnetron magnetic field is often called “electron trap” and the magnetic field “magnetron tunnel”. Because of the fact that the plasma is localized and retained close to the surface all along the magnetron tunnel and electrons are trapped in the magnetron tunnel, the sputtering surface of the target is predominantly eroded by sputtering along the magnetron tunnel. Thereby, on one hand the target is purely exploited and, on the other hand, on the substrate surface to be coated, there occurs an uneven coating distribution, which “pictures” the magnetron tunnel. Additionally, as the erosion depth of the target increases, deposition on the substrate surface becomes more and more focused, which additionally contributes to uneven coating distribution along the surface of the substrate to be coated.

This disadvantage of magnetron sputtering with stationary magnetron tunnels is avoided if the magnetron tunnel is moved along the sputtering surface of the target, which may be achieved by moving the magnetron tunnel generating magnet arrangement along the backside of the target.

Magnetron sputter coating flat, plate-shaped substrates of an electrically isolating material having vias along at least one of the two-dimensionally extended plate surfaces in a manner that on one hand the thickness distribution of the coating along the addressed extended plate surface is at least substantially homogeneous, and, on the other hand, the surfaces of the vias, including sidewalls and bottom surface, become coated without that by such coating of the vias, voids are generated within the vias in that the vias become closed at their entrance is a difficult task and becomes the more difficult the larger that the aspect ratio of the uncoated vias, i.e. the ratio of depth to diameter, is.

It is an object of the invention to improve a sputtering source arrangement, a sputtering system as well as a method of manufacturing metal coated plate-shaped substrates of electrically isolating material having vias along the metal coated plate surface being as well metal-coated, in view of the addressed problem.

This is achieved by a sputtering source arrangement, which comprises, around a geometric axis, a first magnetron sub-source with a first target of a material. The target has a first sputtering surface which defines a plane perpendicular to the addressed geometric axis.

### Definition

When we address a plane which is defined by a surface, namely the sputtering surface, we address a plane which is defined by the two-dimensional locus with respect to which the average of the distance vectors from the surface points of the addressed surface is zero.

The first magnetron sub-source comprises a first magnet arrangement located adjacent a back surface of the first target. The first magnet arrangement is drivingly movable along the first sputtering surface so as to establish a moving close loop first magnetron magnetic field movable along the first sputtering surface.

The sputtering source arrangement further comprises a second magnetron sub-source with a closed, frame-shaped second target of the addressed material and along the periphery of and electrically isolated from the first target. Thus in fact, the second target surrounds the first target along the first target periphery, whereby, considered in radial direction to the geometric axis, the second target frame may overlap the first sputtering surface or may be dimensioned not to overlap the addressed first sputtering surface.

The second target has a second sputtering surface around the geometric axis.

The second magnetron sub-source comprises a second magnet arrangement along and adjacent a back-surface of the second target so as to establish a second magnetron magnetic field along the second sputtering surface.

In one embodiment of the sputtering source, which may be combined with any of the subsequently addressed embodiments of the source, unless in contradiction, the first target is plane and/or circular. Thereby, the addressed sputtering source may exploit the most commonly used shapes of targets also in view of a common shape of substrates with vias which have to be sputter-coated by the source.

In a further embodiment of the sputtering source arrangement, which may be combined with any of the preaddressed embodiments and embodiments of the source arrangement still to be addressed, unless in contradiction, the second sputtering surface defines, in cross-sectional planes which contain the geometric axis, a pair of substantially straight lines.

In a further embodiment of the sputtering source arrangement, which may be combined with any of the preaddressed embodiments and embodiments still to addressed of the arrangement, unless in contradiction, the second sputtering surface defines around the geometric axis a surface which is parallel to the geometric axis and thus e.g. a cylindrical surface around the addressed geometric axis or which is perpendicular to the geometric axis and thereby especially facing away from the first sputtering surface, or is cone-shaped, opening in a direction along the geometric axis and away from the first sputtering surface.

In a further embodiment of the source arrangement, which may be combined with any of the preaddressed embodiments and embodiments of the arrangement still to be addressed, unless in contradiction, the sputtering source arrangement comprises a metal frame between the first sputtering surface and the second sputtering surface, which extends along the periphery of the first sputtering surface and along the second sputtering surface. The metal frame which thus is disposed between the first sputtering surface and the second sputtering surface is operable as an anode and thus electrically isolated from the first as well as from the second targets. Alternatively, the metal frame is operable electrically on a floating potential and is thus electrically isolated from the first as well as from the second targets. In a third alternative, the addressed metal frame is electrically connectable to the second target.

In a further embodiment of the sputtering source arrangement, which may be combined with any of the preaddressed embodiments and embodiments of the arrangement still to be addressed, unless in contradiction, the arrangement comprises a frame-shaped anode which is arranged, in a direction along the geometric axis and pointing away from the first sputtering surface, subsequent to and along the second sputtering surface.

According to a further embodiment of the sputtering source arrangement, which may be combined with any of the preaddressed embodiments and embodiments of the arrangement still to be addressed, unless in contradiction, the second magnet arrangement comprises a frame of magnets along the backside of the second target. The magnetic dipoles of these magnets are arranged in sectional planes which contain the geometric axis.

In an embodiment of the sputtering source arrangement which may be combined with any of the preaddressed embodiments and embodiments still to addressed of this arrangement, unless in contradiction, the second magnet arrangement is one of stationary with respect to the second sputtering surface and of drivingly movable with respect thereto. Thereby and in one embodiment the magnet arrangement is movable in directions which are in sectional planes containing the geometric axis as well as along the second sputtering surface in azimuthal direction with respect to the geometric axis.

In a good embodiment such movement is realized by a snake-like shaped moving, wobbling along the second sputtering surface, wobbling from one edge of the second sputtering surface to the other edge.

According to a further embodiment of the sputtering source arrangement, which may be combined with any of the preaddressed embodiments and embodiments of the arrangement still to be addressed, unless in contradiction, there is provided a cooling system which includes a pipe system for a cooling medium along the first and along the second target, which cooling system in one embodiment comprises a first cooling sub-system for the first target and a second cooling sub-system for the second target.

The sputtering system according to the present invention comprises a sputtering source arrangement, namely a sputtering source arrangement as was addressed above, possibly constructed according to one or more than one of the embodiments addressed above in context with the sputtering source arrangement. The sputtering system further comprises a power source arrangement which is operationally connectable to the first and to the second sub-sources, which is constructed to operate the first sub-source in a first mode, which is a pulsed DC mode and the second sub-source in a second mode.

### Definition

We understand under a “pulsed DC” applying power in a pulsed manner. The resulting power pulse train has a DC-offset. Thereby, the DC offset may e.g. be half the pulse amplitudes, which results in a pulse train at which the pulse “off” level is at practical zero, irrespective of the duty cycle of the pulse train.

In one embodiment of the sputtering system, which may be combined with any embodiment of this system still to be addressed, unless in contradiction, the pulsed DC mode is a HIPIMS mode.

In an embodiment of the just addressed embodiment the power source arrangement operates the first target as follows: Adapted to the prevailing extent of the first sputtering surface so, that for an assumed extent of said first sputtering surface of 2240 cm² there becomes valid:
Peak of the current pulses: 600-1000 A
Length of current pulses: 100 μsec to 200 μsec
Duty cycle, i.e. pulse ON- to pulse OFF-time ratio 5% to 15%

In a further embodiment of the addressed sputtering system which may be combined with any of the preaddressed system embodiments as well as with such embodiments still to be addressed, unless in contradiction, the second mode in which the second sub-source is operated is a DC mode or a further pulsed DC mode.

In a further embodiment of the sputtering system which may be combined with any of the preaddressed system embodiments as well as with such embodiments still to be addressed, unless in contradiction, the second mode by which the second sub-source is operated is a HIPIMS mode.

In a further embodiment of the sputtering system which may be combined with any of the preaddressed system embodiments as well as with such embodiments still to be addressed, unless in contradiction, the power source arrangement is time-controllable so as to establish said first mode during a first timespan and the second mode during a second timespan, in one good embodiment thereof the addressed timespans are adjustable.

In a further embodiment of the just addressed embodiment the second timespan is started after starting of the first timespan.

In a further embodiment of that embodiments, wherein the power source arrangement is time-controllable to establish the respective first and second modes during the first timespan and the second timespan, the first and second timespans do not overlap.

In a further embodiment of the just addressed embodiment the time-controlled power source arrangement operates at least one of the second target as an anode, when the first mode is in enabled and of the first target as an anode, when the second mode is operated.

In a further embodiment of the system, which may be combined with any preaddressed system embodiment or with any such embodiment still to be addressed, unless in contradiction, one of the first and second targets is operated as an anode when the other of the first and second targets is operated as an anode and vice versa.

In a further embodiment of the sputtering system, which may be combined with any of the preaddressed system embodiments and system embodiments still to be addressed, unless in contradiction, the power source arrangement comprises a first power source operationally connected to first target and a second power source operationally connected to the second target.

In a further embodiment of the sputtering system, which may be combined with any of the preaddressed embodiments and embodiments of the system still to be addressed, unless in contradiction, the system further comprises a substrate holder for a plate-shaped substrate. The substrate holder is constructed to hold a plate-shaped substrate in a plane perpendicular to the geometric axis. The surface of a substrate held in the substrate holder and to be sputter coated facing towards the first and second targets.

In a further embodiment of the sputtering system in an embodiment as just addressed the system comprises a biasing power source, in a good embodiment an RF biasing power source which is operationally connectable to the substrate holder.

In a further embodiment of the sputtering system, which may be combined with any system embodiment already addressed and still to be addressed, unless in contradiction, and wherein a substrate holder is provided, the substrate holder is constructed to establish a distance d along the geometric axis and between the first sputtering surface and a surface to be sputter coated of a plate-shaped substrate on the substrate holder and with respect to a diameter D of a circle circumscribing the first sputtering surface, considered in a direction along the geometric axis, so that there is valid:

0.125 D≦d≦0.5 D.

In a further system embodiment, which may be combined with any such embodiment already addressed and still to be addressed, unless in contradiction, and which comprises a substrate holder, the first sputtering surface overlaps the periphery of a plate-shaped substrate on the substrate holder.

In a further system embodiment, which may be combined with any such embodiment already addressed, and which comprises a substrate holder, considered in a direction along the geometric axis, the second target is arranged subsequent the first target and a substrate, which is held by said substrate holder is arranged subsequent the second target.

The present invention is further directed on a method of manufacturing metal-coated, plate-shaped substrates of electrically isolating material having vias along the metal-coated plate surface, the vias being as well metal-coated. The addressed manufacturing method comprises coating a plate-shaped substrate of electrically isolating material having vias along at least one of the plate surfaces by means of a sputtering system as was addressed above and possibly such sputtering system according to one or more than one of the addressed embodiments.

In one variant of the addressed method, which may be combined with any method variant still to be addressed, unless in contradiction, the vias in the electrically isolating material plate-shaped substrate have an aspect ratio of at least 10:1 before being coated.

In a variant of the method, which may be combined with any of the preaddressed method variants and such variants still to be addressed, unless in contradiction, a plate-shaped substrate with vias is provided perpendicularly to the geometric axis, whereby the vias face the first sputtering surface. Then, the substrate is first magnetron sputter-coated with a metal by means of the first sputtering surface, whereby the first target is operated in a HIPIMS mode and the first magnet arrangement is moved in a driven manner along the first sputtering surface. The substrate is additionally second magnetron sputter-coated with the addressed metal by means of the second sputtering surface.

In one variant of the just addressed system variant, there is established the first sputter-coating during a first timespan T₁, and there is established the second sputter-coating during a second timespan T₂. The timespans T₁ and T₂ are thereby selected in one of the following modes:
When T₁ is selected of equal extent as T₂ one of the following prevails:
   T₁ is established simultaneously with T₂.
   T₂ is started after the start and before the end of T₁;
   T₂ is started at or after the end of T₁
   T₁ is started after starting and before the end of T₂.
   T₁ is started at or after the end of T₂.
When T₁ is selected of longer extent than T₂ one of the following prevails:
   T₂ is within T₁
   At least a part of T₂ is subsequent to the end of T₁
   At least a part of T₁ is subsequent to the end of T₂
When T₂ is selected of longer extent than T₁ one of the following prevails:
   T₁ is within T₂
   At least a part of T₁ is subsequent the end of T₂.
   At least a part of T₂ is subsequent the end of T₁.
   Whereby in a today practiced variant T₂ starts at or after the end of T₁.

In a further variant of the method, wherein first and second timespans are exploited, there is operated at least one of the first target during the first timespan T₁ and of the second target during the second timespan T₂ more than one time.

In a further variant of the method, which may be combined with any method variant already addressed and such variants still to be addressed, unless in contradiction, the second target is operated by one of DC mode, pulsed DC mode and HIPIMS mode.

In a variant of the method, which may be combined with any preaddressed method variant and such variants still to be addressed, unless in contradiction, the first and the second target are operated by an output-controllable common power source.

In one variant of the just addressed variant of the method, the common power source is operationally interconnected between the first and the second targets.

In one variant of the just addressed method variant, the common power source operates the first target in HIPIMS mode, the second target in one of DC mode, pulsed DC mode and HIPIMS mode.

In a variant of the just addressed variant, the common power source operates the second target in pulsed DC or in HIPIMS mode, thereby inverting pulse polarity when changing from sputter operating the first target to sputter operating the second target.

In a further variant of the method, which may be combined with any preaddressed method variant and such variants still to be addressed, unless in contradiction, the second target is exploited as a first anode in a timespan, during which the first target is sputter-operated, and the first target is exploited as a second anode in a timespan during which the second target is sputter-operated.

In a further variant of the method, which may be combined with any preaddressed method variant and such variant still to be addressed, unless in contradiction, during sputter-operating the first and the second target Rf bias power is applied to the substrate.

In one variant of the just addressed method variant, there is applied a different Rf bias power to the substrate for sputtering from the first target, then for sputtering from the second target.

In a further variant of the method, which may be combined with any preaddressed method variant and such variant still to be addressed, unless in contradiction, the thickness distribution of material deposited on said plate-shaped substrate of electrically isolating material and along the plate surface is adjusted by adjusting the ratio of a first timespan, during which said first target is sputtered and of a second timespan, during which the second target is sputtered.

In a further variant of the just addressed method variant, the addressed thickness distribution is adjusted during target life.

The invention under all its different aspects shall now be further explained with the help of examples and of figures. The figures show:

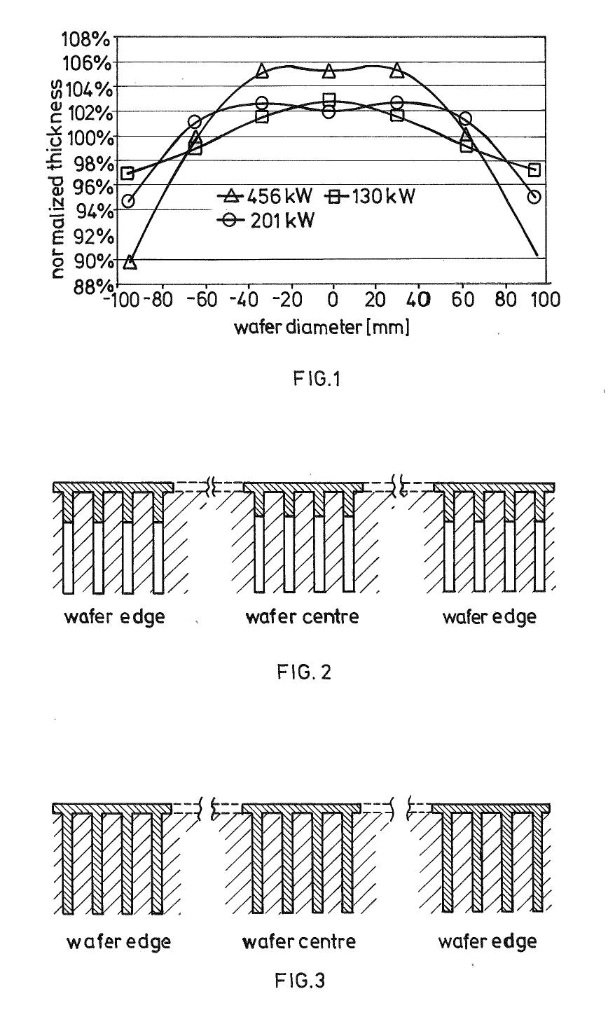

FIG. 1 film thickness distribution of HIPIMS deposited Ti as a function of pulse peak power, from 2009 society of vacuum coaters 505/856-7188, 52^{nd} annual technical conference proceedings, Santa Clara, Calif., May 9-14, 2009 ISSN 0737-5921;

FIG. 2 schematically, incomplete electro plating in 10:1 vias as a result of DC sputtered seed layer;

FIG. 3 schematically, complete electro plating in 10:1 vias with HIPIMS—metal ions—sputtered seed layer;

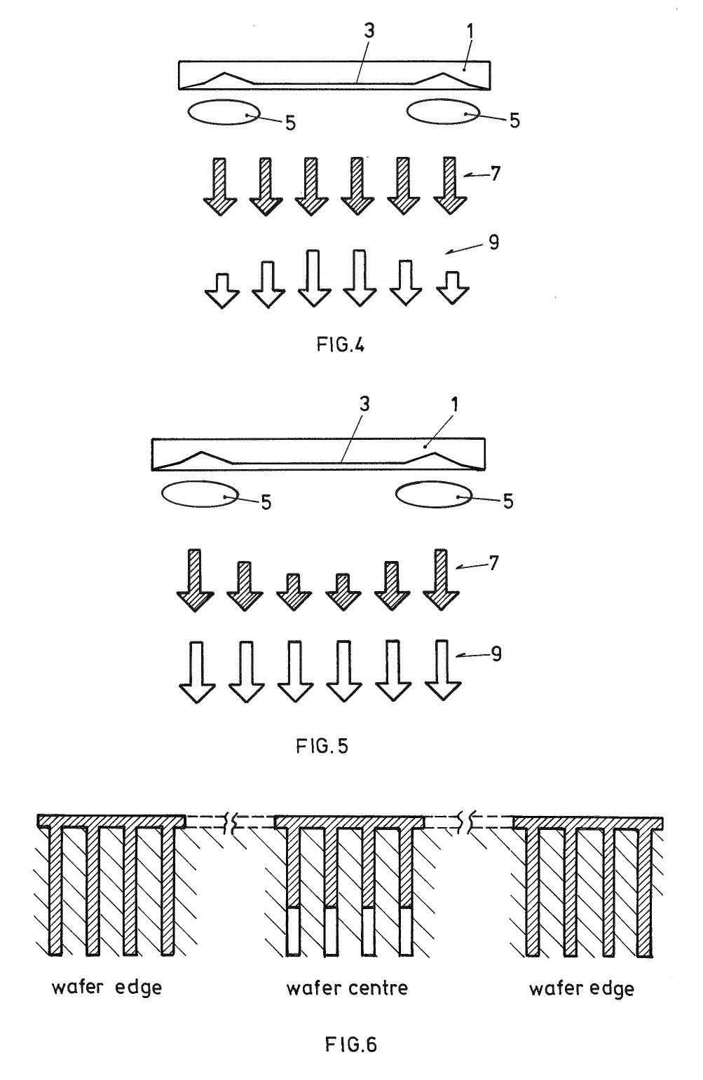

FIG. 4 schematically, a planar magnetron source with a uniform metal ion flux and a dome-shaped metal atom flux;

FIG. 5 schematically, a planar magnetron source with a uniform metal atom flux and a bowl-shaped metal ion flux;

FIG. 6 in a representation in analogy to those of the FIGS. 2 and 3, electro-plating of 10:1 vias with incomplete filling in the substrate center due to reduced metal ion flux as of FIG. 5;

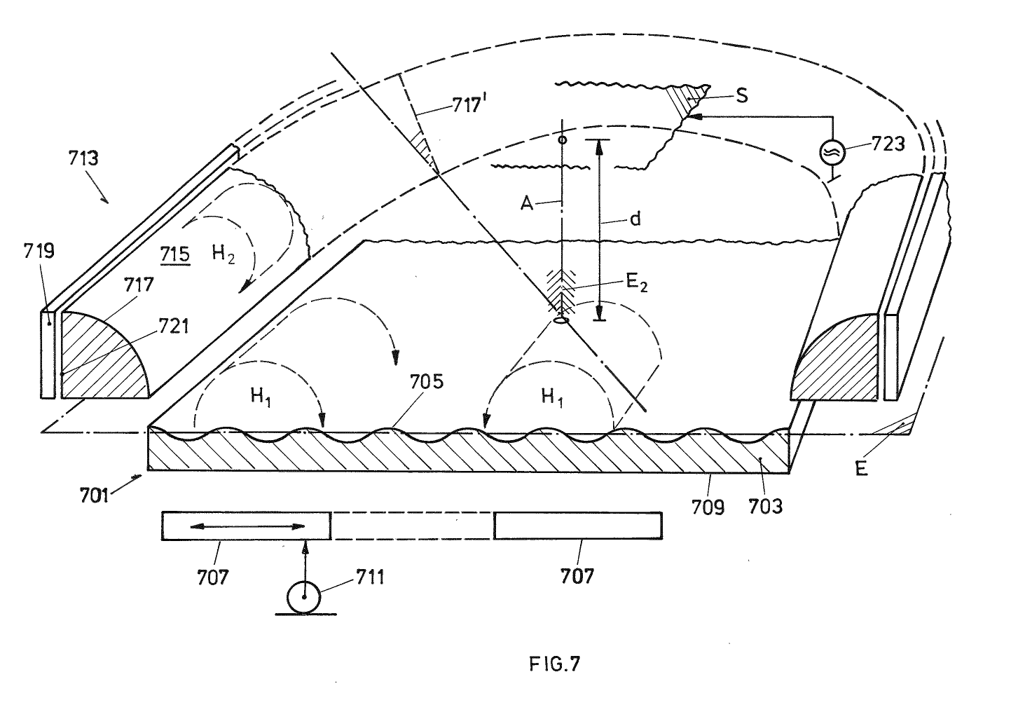

FIG. 7 schematically and simplified, in a partly cut perspectivic view, the principle of a sputtering source arrangement according to the present invention and of a sputtering system according to the invention as for practicing the method of manufacturing according to the invention;

FIG. 8 by means of a cross-sectional representation through a part of a target as exploited in the embodiment of FIG. 7, in an enlarged view generically the sputtering surface so as to explain a definition of a “plane defined by the sputtering surface”;

FIG. 9 most schematically and simplified, one embodiment of a second target of a second magnetron sub-source at the sputtering source arrangement according to the invention and as exemplified in FIG. 7;

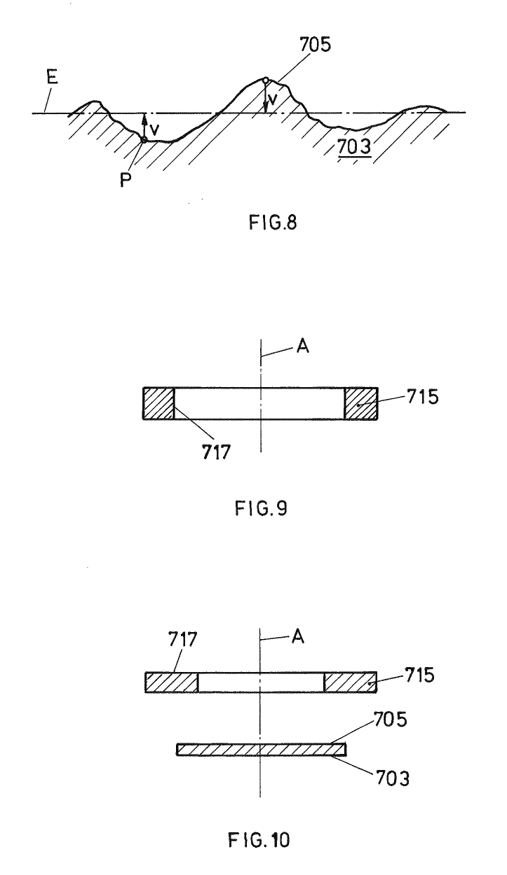

FIG. 10 in a representation in analogy to that of FIG. 9, a further embodiment of a second target of the second magnetron sub-source as exploited in a sputtering source arrangement according to the invention and as exemplified in FIG. 7;

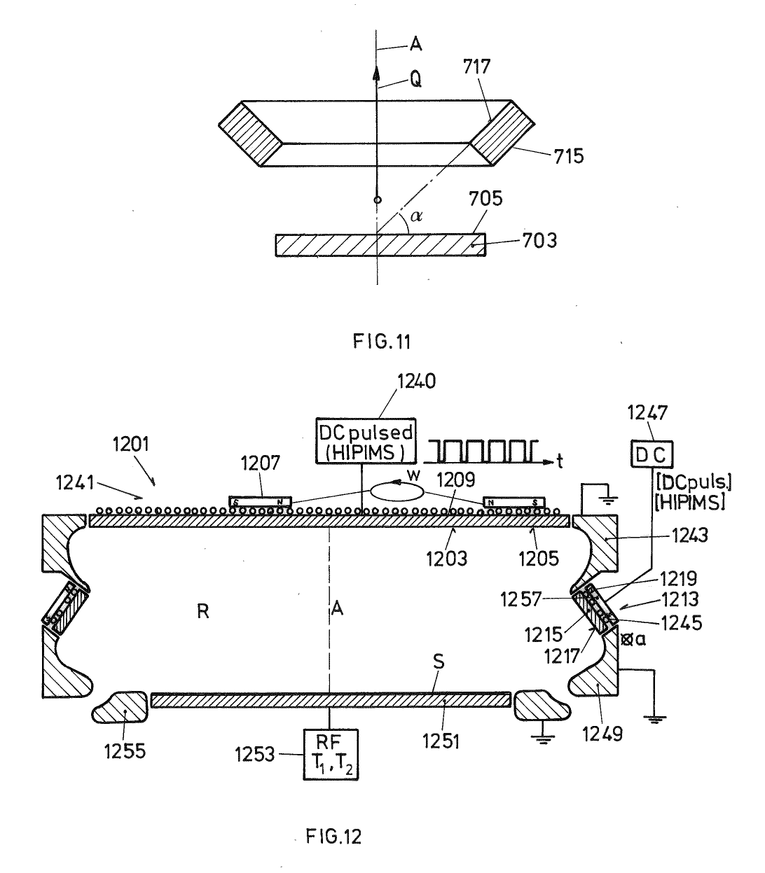

FIG. 11 still in a representation in analogy to those of the FIG. 9 or 10, a still further embodiment of a second target of a second magnetron sub-source as exploited in a sputtering source arrangement according to the invention and as exemplified in FIG. 7;

FIG. 12 schematically and simplified, an embodiment of a sputtering system according to the invention with a sputtering source arrangement according to the invention for operating the manufacturing method according to the invention in a schematic cross-sectional representation and based on the generic embodiment of FIG. 7;

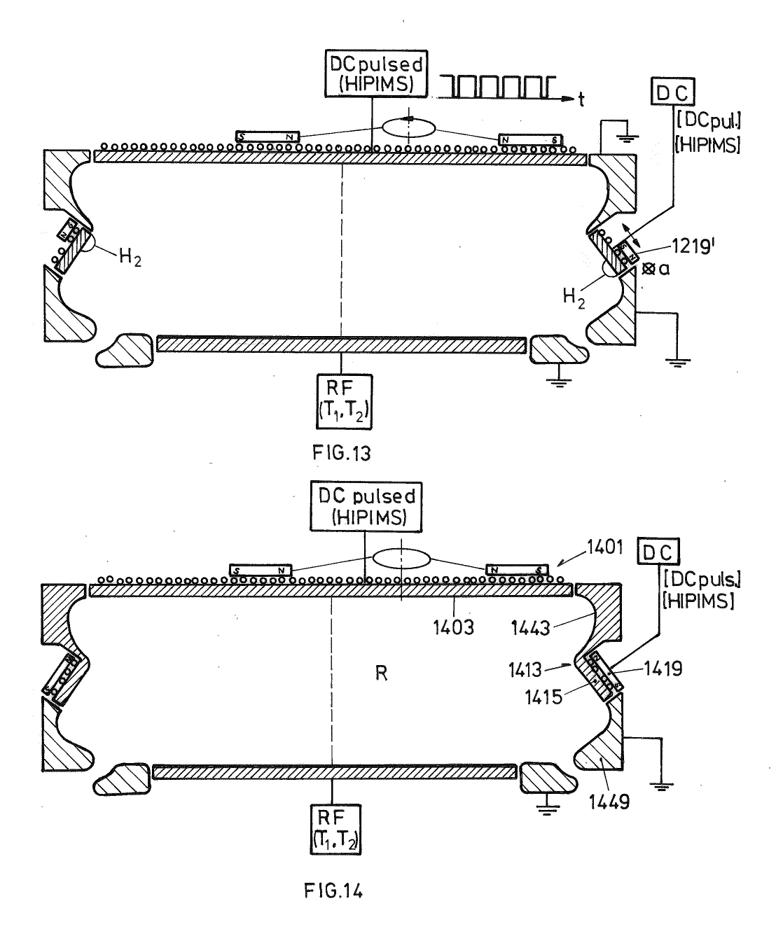

FIG. 13 in a representation in analogy to that of FIG. 12, a further embodiment of the sputtering system, sputtering source arrangement as exploited to operate the manufacturing method according to the invention and based on the generic embodiment of FIG. 7 as well;

FIG. 14 still in a representation in analogy to those of the FIGS. 12 and 13, a still further embodiment of the sputtering system, and the sputtering source as exploited for the manufacturing method, all according to the invention and based on the generic embodiment as of FIG. 7;

FIG. 15 still in a representation according to the FIGS. 12 to 14, a further embodiment of a sputtering system, and sputtering source arrangement, as exploited by the method for manufacturing, all according to the present invention and based on the generic embodiment as of FIG. 7;

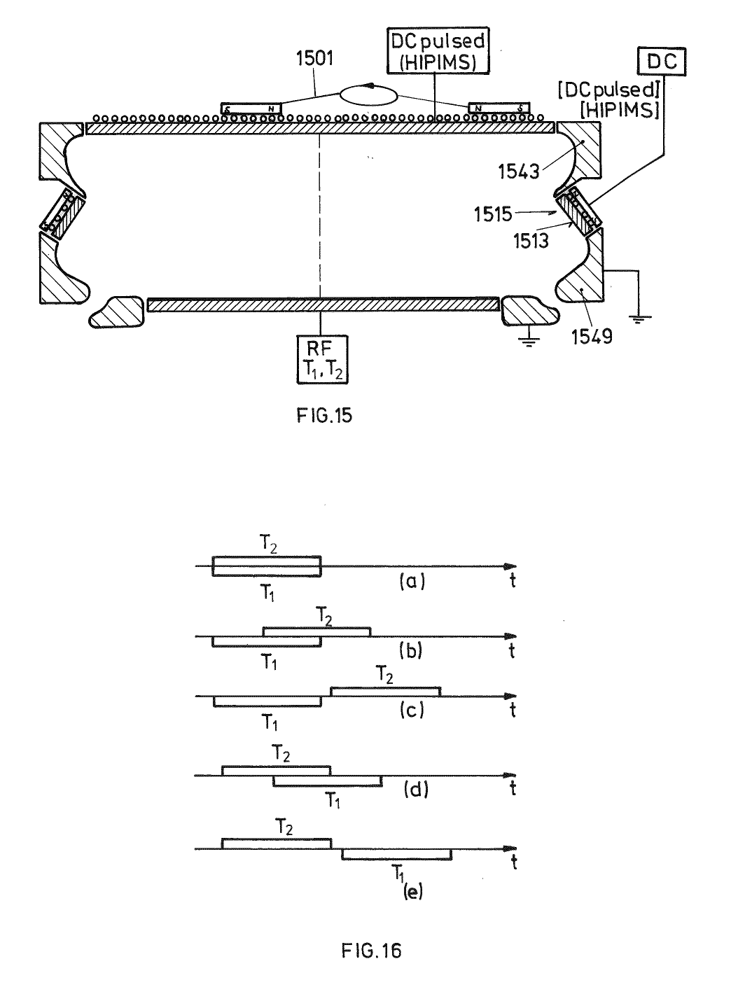

FIG. 16 different possibilities of staggering timespans T₁ and T₂ of operating a first and a second magnetron sub-source and as exemplified with the help of the FIGS. 7 to 15 in the case that both timespans are of equal length;

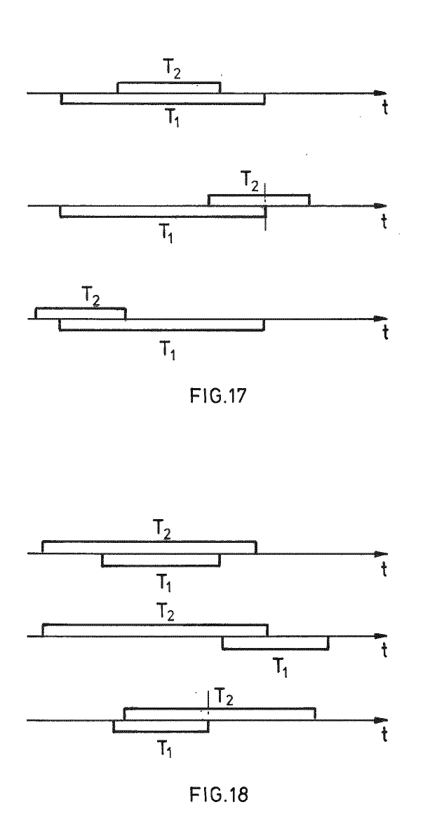

FIG. 17 in a representation in analogy to that of the FIG. 16, staggering possibilities if the timespan T₁ of operating the first magnetron sub-source is longer than the timespan T₂ of operating the second magnetron sub-source;

FIG. 18 in a representation in analogy to those of the FIGS. 16 and 17, staggering possibilities if the timespan T₂ of operating the second magnetron sub-source is longer than the timespan T₁ of operating the first magnetron sub-source as has been exemplified with the help of FIGS. 7 to 15;

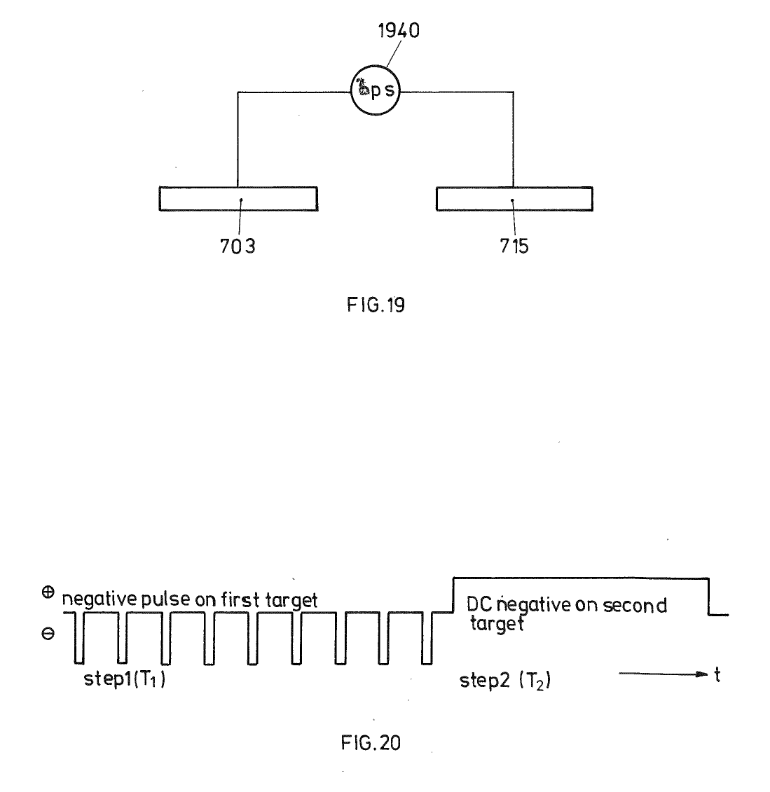

FIG. 19 most generically and simplified, a further embodiment of operating the first and the second magnetron sub-sources as have been exemplified with the help of the FIGS. 7 to 15 by means of a common bipolar power source;

FIG. 20 a two-step process embodiment with a bipolar power supply, whereby the first magnetron sub-source is operated in pulsed mode during a step 1 of time extent T₁ and the second magnetron sub-source in DC mode in step 2 of time extent T₂;

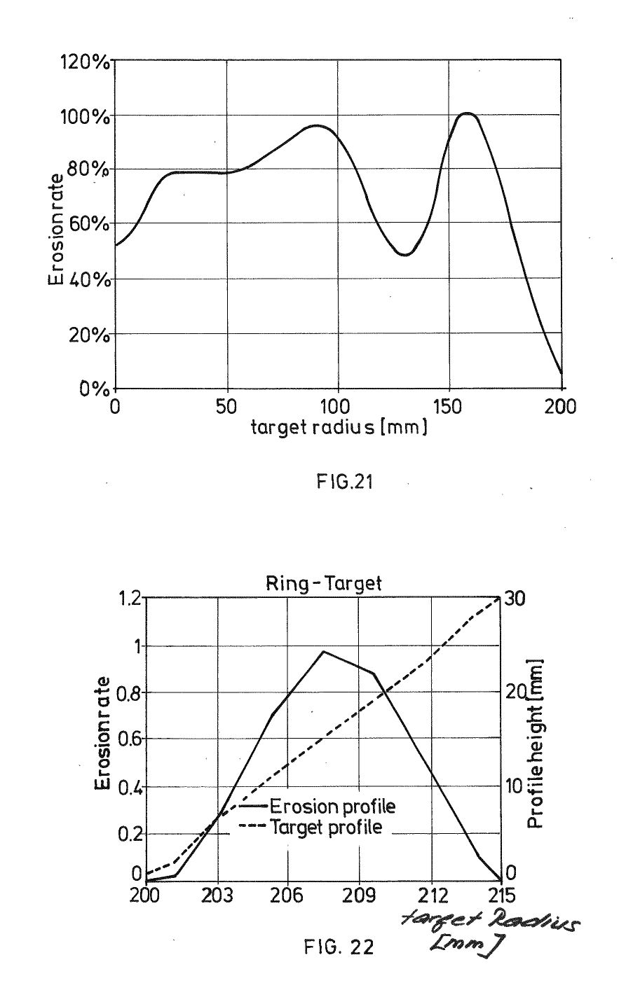

FIG. 21 an erosion profile of the first target of the first magnetron sub-source as exemplified in the embodiment of the FIGS. 7 to 15, the first target being planar and circular, according to Example 1;

FIG. 22 the erosion profile of the second target of a second magnetron sub-source with a slope, according to FIG. 11, of α=45°, inner and outer radius of 200 and 250 mm respectively, and according to Example 1;

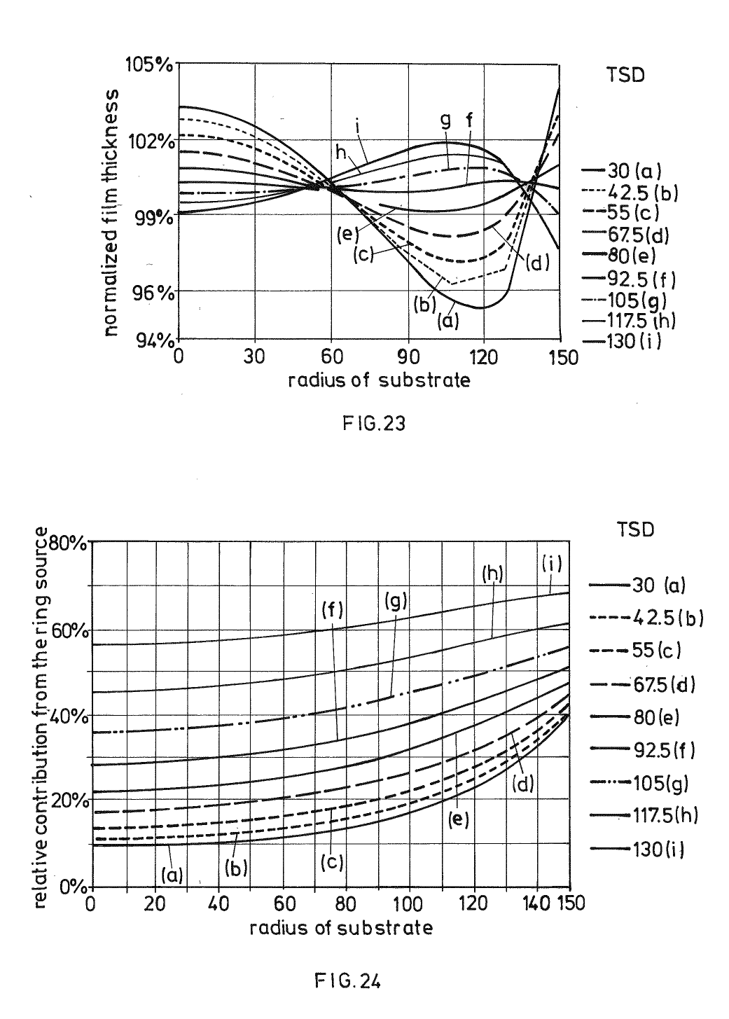

FIG. 23 the uniformity profile optimized by different ratio of contribution by the second magnetron sub-source relative to the contribution of the first magnetron sub-source according to the profile as of FIGS. 21 and 22, and Example 1, for varying TSD_R (=TDS) between 30 mm and 130 mm;

FIG. 24 still with respect to Example 1 and thus in context with the FIGS. 21 to 23, the relative contribution of the second magnetron sub-source to the total film thickness on the substrate to adjust the uniformity for TSD_R varying between 30 mm and 130 mm for the optimized deposition profile according to FIG. 23;

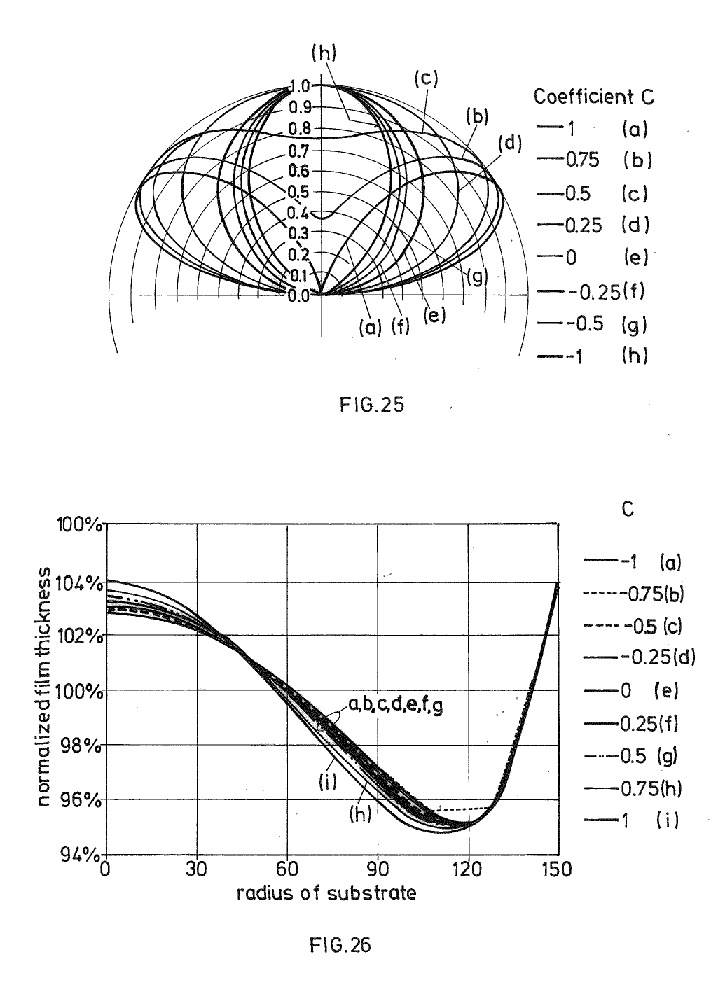

FIG. 25 sputter emission profiles in polar-diagram-form (not shown) as described by formula (2) of the description with varying coefficient C;

FIG. 26 uniformity profiles for closest TSD_R of 30 mm for target material emission characteristics with coefficient C between −1 and 1 and still according to Example 1;

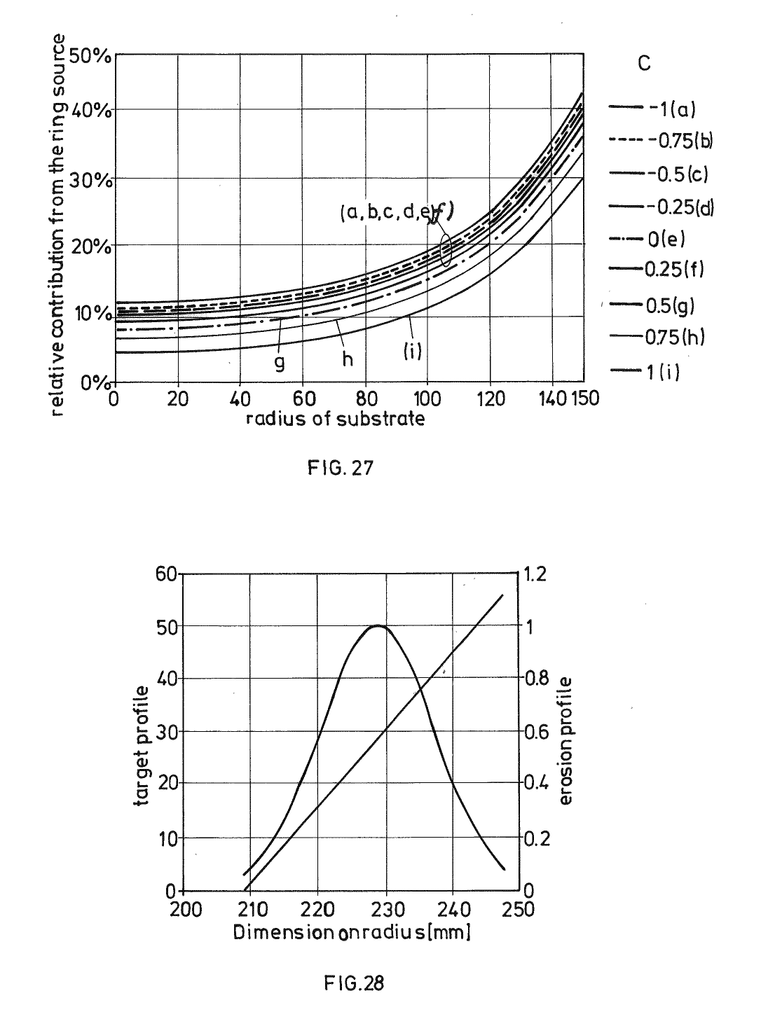

FIG. 27 the relative contribution of the second magnetron sub-source to the total film thickness to adjust the uniformity for the closest TSD_R of 30 mm and for target emission characteristics with a coefficient between −1 and 1 as of Example 1;

FIG. 28 the erosion profile of the second target of the second magnetron sub-source with an angle α according to FIG. 11 of 55° and having inner and outer radius of 216 and 255 mm respectively as of Example 2;

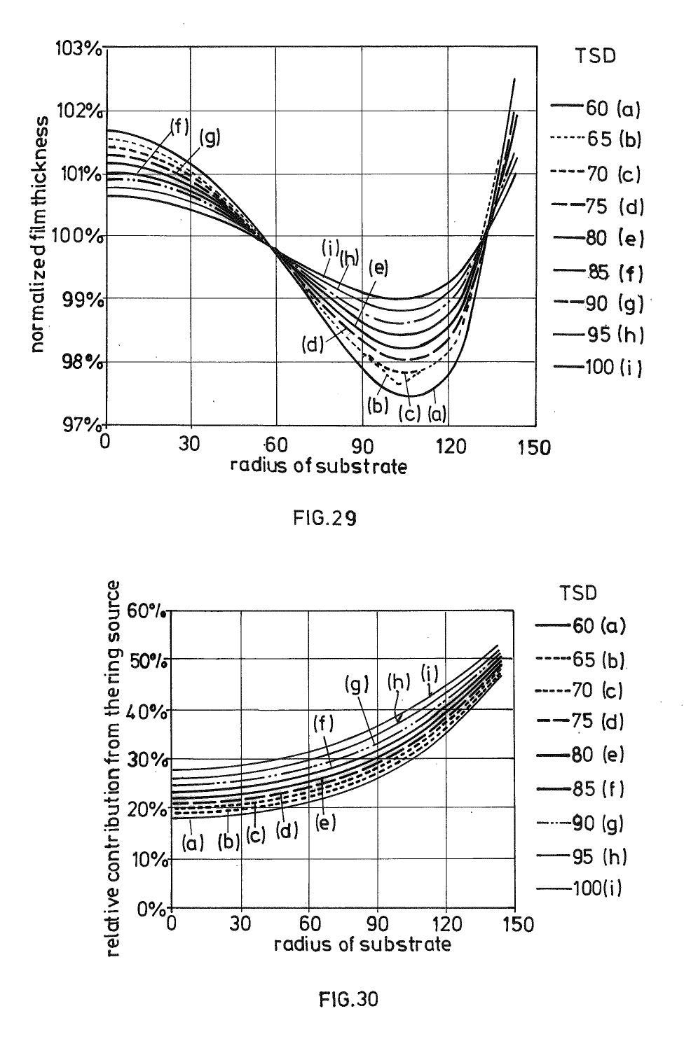

FIG. 29 the uniformity profiles optimized by superposition of the effect of the second magnetron sub-source to the effect of the first magnetron sub-source for TSD_R varying between 60 mm and 100 mm as of Example 2;

FIG. 30 the relative contribution of the second magnetron sub-source to the total film thickness to adjust the uniformity optimized by superposition to the contribution of the first magnetron sub-source, for TSD_R between 60 mm and 100 mm as of Example 2;

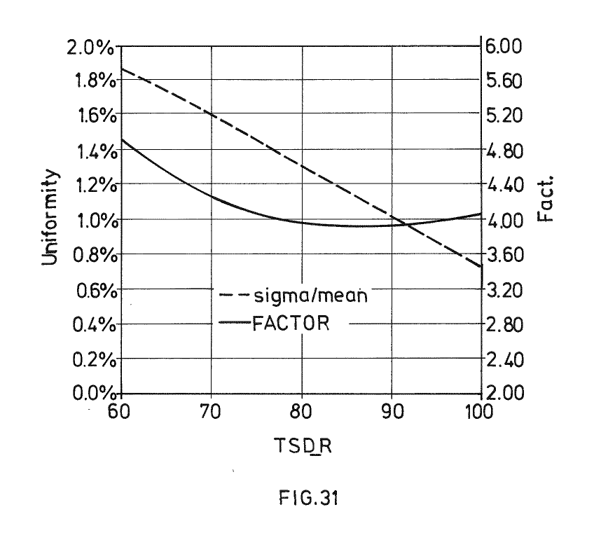

FIG. 31 the calculated uniformity and superposition factor vs. TSD_R as for Example 2.

### INTRODUCTORY EXPLANATION

High-power impulse magnetron sputtering (HiPIMS, HIPIMS) is a method for physical vapor deposition—PVD—of thin films, which is based on magnetron sputter-deposition. HIPIMS utilizes extremely high power density of the order of kW.cm-2 in short pulses (impulses) of tenths of μsec extent at low duty cycle (ON/OFF time ration of <10%). A distinguishing feature of HIPIMS compared to common magnetron sputtering is its high degree of ionization of the sputtered off metal and high rate of molecular gas dissociation. With a conventional DC magnetron sputtering process the ionization of the sputtered-off material is increased by increasing the cathode power. The limit thereof is determined by the increased thermal load of the cathode and of the substrate to be coated. HIPIMS is applied at this point: The average cathode power remains low (1 to 10 kW) because of the small duty cycle. This allows the target to cool down during the OFF-times, resulting in an increased process stability. HIPIMS is a special type of pulsed DC magnetron sputtering.

The principle of HIPIMS (High-power Impulse Magnetron Sputtering) and its application for the material deposition into vias, especially TSV (Through Silicon Vias) has been described e.g. in WO 08/071734 A2, WO 08/071732 A2, WO 09/053479 A2 and in “Society of vacuum coaters 505/856-7188, 52^{nd} annual technical conference proceedings, Santa Clara, Calif., May 9-14, 2009 ISSN 0737-5921”.

In the latter document it is described that for a given target, a given target to substrate distance and a given rotating magnet for generating the magnetron magnetic field the film thickness distribution develops from flat to dome-shaped when the pulse peak power HIPIMS discharge is increased. FIG. 1 shows the film thickness distribution for HIPIMS Ti deposition as a function of pulse peak power. FIG. 1 is taken from the addressed Society of vacuum coaters 505/856-7188, 52^{nd} annual technical conference proceedings, Santa Clara, Calif., May 9-14, 2009 ISSN 0737-5921.

There exists a need to provide a sufficiently thick layer, especially a sufficiently thick seed layer, in the bottom and along the sidewalls of vias as of TSV (Through Silicon Vias) with high aspect ratios between 5:1 and 10:1 or even higher, e.g. to enable later electro-plating. The deposition on the walls/bottom of the vias may thereby consist of an adhesion or barrier layer which may be of Ti or Ta, and a Cu seed layer, which is responsible for carrying the current for electro-plating into the via. With a DC magnetron sputtering setup working at a close target to substrate distance (TSD) it is practically impossible to provide material layers and thereby also the addressed seed layer in high aspect ratio vias as of TSVs due to the wide angular distribution of sputtered off material, customarily a metal. As a result later electro-plating will result in incomplete filling of the vias as depicted in FIG. 2. FIG. 2 shows most schematically the degree of via filling when propagating across the wafer or substrate, i.e. from one wafer edge via wafer center, to the opposite wafer edge. The areas shown in black are the areas along the wafer and within the vias of 10:1 aspect ratio which are covered and filled respectively by the electro-plating, a DC magnetron-sputtered seed layer having been applied.

The HIPIMS process can provide a sufficiently high ion flux, in the addressed example sufficiently high Cu ion flux, to the substrate so that a complete electro-plating is possible as shown in FIG. 3 in a schematic representation in analogy to the representation of FIG. 2. This can be achieved by a pulse peak power of at least 300 kW, combined with an increased target substrate distance—TSD. Thus, it is a requirement to achieve a sufficiently uniform layer deposition inside the vias, so that complete electro-plating is subsequently achieved throughout the substrate surface from substrate periphery to substrate center, as schematically shown in FIG. 3.

The present invention is to one part based on the experience that with a HIPIMS process, due to the limited target size, for a given magnetron sputter source with a uniform metal ion flux, the metal atom flux is stronger towards the center of the target and weaker towards the edge or periphery of the target. This is schematically shown in FIG. 4. Therein, most schematically, a HIPIMS operated target 1 is shown with an erosion profile of the sputtering surface 3 due to concentration of the plasma 5 by the magnetron magnetic field. The arrows 7 schematically show the distribution of metal ions along the sputtering surface 3 of target 1, whereas the arrows 9 indicate the metal atom distribution. It may be seen that the metal atom flux is dome-shaped.

Thus, according to FIG. 4 by the HIPIMS process, from the flux of metal ions and the flux of metal atoms, the uniformity of the flux of metal ions is optimized.

As a result the thickness profile on a substrate surface—i.e. in the field—becomes dome-shaped while deposition in the vias is uniform throughout the substrate surface or may even show thickened deposition in vias provided towards the edge or periphery of the substrate.

The present invention is further based on a second recognition. Departing from the explanations with respect to FIG. 4, the thickness along the flat surface of the substrate to be coated can be improved with respect to uniformity and thus dome-shaped thickness distribution may be compensated by using an erosion profile from the target, which results in an increased eroding of the sputtering surface close to the target edge or periphery. This may be realized by respectively constructing the magnet arrangement and tailoring its movement along the backside of the target, i.e. by appropriately tailoring the relative movement of target to magnet arrangement as e.g. of a mutual rotating movement.

The recognition is the disadvantageous fact that lacking plasma density in the center of the target of the magnetron source, less metal ions current flux is present in the center of the sputtering surface. This is shown in FIG. 5 in a representation in analogy to that of FIG. 4. It may be seen that in this case the metal ion distribution becomes bowl-shaped as shown by the arrows 7. Thus, in this case, uniformity of metal atom flux is optimized, in opposition to uniformity of metal ion flux. As a result the electro-plating of high-aspect ratio vias as of vias with an aspect ratio of 10:1 in the center of the substrate becomes incomplete. Thus, as recognized by the inventors, it is hardly possible to achieve homogeneous covering of both the substrate surface as well as the vias surfaces.

As already discussed above, using a magnet system which allows for more erosion along the target edge or periphery improves the uniformity of coating thickness distribution along the extended surface of the substrate being coated, but has the disadvantage that the ion density profile concentrates more towards the target edge, which may lead to incomplete coverage of the surfaces of vias provided adjacent to the center of the substrate. Using a very small target to substrate distance (TSD) is not advisable, since there may come up interference between the high-density plasma adjacent the sputtering surface of the target and a bias of the substrate. Also for very high aspect ratios e.g. of 10:1 or more of vias, as of TSVs, one should use a target to substrate distance which is higher than for HIPIMS sputter coating flat substrates. This may be said “medium throw sputtering” compared to long-throw sputtering, where the directionality of material is given by narrow angle sputtering and not by the ionized material.

Another option to face the addressed recognition is to apply a target with a larger diameter with respect to the extent of a substrate with vias to be coated, which can also help to correct the uniformity of coating deposition on the substrate. The disadvantages of this option are:
Heavy and more expensive targets are needed;
To achieve the same ionization degree more average power is required;
The larger target leads to a wider angular distribution of the material impinging upon the surface of the substrate to be coated.

With an eye on the metal ion and metal atom distribution as schematically shown in FIG. 5, FIG. 6 shows in a representation in analogy to that of the FIGS. 2 and 3 the resulting electro-plating in 10:1 vias, incomplete in vias in the substrate center due to the reduced metal ion flux in the center area.

In FIG. 7 the principle of a sputtering source arrangement according to the present invention, part of a sputtering system according to the invention and as exploited in the method of manufacturing according to the invention, is shown in a perspectivic, most schematic and simplified view. Around a geometric axis A a first magnetron sub-source 701 comprises a first target 703 of a material, as of a metal. The first target 703 has a first sputtering surface 705. This first sputtering surface 705 defines for a plane E, which is perpendicular to the geometric axis A. As shown in FIG. 8 the plane E may be defined by a two-dimensional locus plane defined in that the average of all distance vectors ν̅ from all the points P of the sputtering surface 705 with respect to that locus plane E is zero.

Back to FIG. 7, the first magnetron sub-source 701 comprises a first magnet arrangement adjacent a back surface 709 of the first target 703, which is drivingly movable along the first sputtering surface 705 as schematically shown by drive 711. Thereby, there is established a moving close loop first magnetron magnetic field, as is shown in dashed line and most schematically in FIG. 7, H₁. The sputtering source arrangement further comprises a second magnetron sub-source 713, which has a closed, frame-shaped second target 715 of the same material as the first target 703, as of the same metal. The closed, frame-shaped second target 715 is provided along the periphery of and electrically isolated from the first target 703, as is schematically shown in FIG. 7 in dashed line. The second target 715 has a second sputtering surface 717, which is arranged around the central axis A, thus in fact forming a loop around said axis A. A second magnet arrangement 719 is provided along and adjacent the back-surface 721 of the second target 715 and establishes a second magnetron magnetic field along the second sputtering surface 717 as schematically shown by H₂ in FIG. 7, which forms a closed loop along the second sputtering surface 717, looping around geometric axis A.

The first target 703 may be plane, i.e. defining for a plane sputtering surface 705 before material has been sputtered off the target.

Further, the first target 703 may be in a view in direction along geometric axis A of any desired shape, but is in one embodiment circular. Then the second target 715 is ring-shaped.

Although the shape of the second sputtering surface 717 may be selected according to the respective application. In a today practiced embodiment the addressed sputtering surface 717 defines a pair of substantially straight lines in the sectional planes which contain the geometric axis A. In FIG. 7 such a sectional plane which contains the geometric axis A is shown by plane E2, defining thereby one of the pair of substantially straight lines 717′ of the second sputtering surface 717.

Moreover, the second sputtering surface 717 may in one embodiment define, around geometric axis A, a surface which is parallel to the geometric axis A as is schematically shown in FIG. 9.

Further, the second sputtering surface 717 may be perpendicular to the geometric axis A as schematically shown in FIG. 10. Thereby, in a good embodiment the second sputtering surface 717 faces away from the first sputtering surface 705.

Alternatively, the second sputtering surface 717 may be cone-shaped as schematically shown in FIG. 11, opening in direction along the geometric axis A, pointing away from the first sputtering surface 705, as indicated in FIG. 11 by the arrow Q.

Further embodiments of the sputter source arrangement as well as more details about the method of manufacturing shall be explained by the following examples and figures, which are more detailed, whereby all these examples and realization forms are based on the principle sputtering source arrangement as has been explained in context with FIG. 7.

Specific features which will be described in context with the more detailed embodiments may be combined in any combination and applied to the embodiment of FIG. 7, unless being in mutual contradiction.

In today's practiced forms of the sputtering source arrangement as of FIGS. 12 to 15 the first magnetron sub-source is realized by a planar, pulsed circular magnetron source. With an eye on FIG. 7 this means that target 703 is circular and plane. The substrate is thereby positioned in a distance of more than ⅛ and less than ½ of the diameter of the circular target from the first sputtering surface.

Addressing a target 703 as of FIG. 7, which is not circular and even possibly not planar, the more generic rule for positioning the substrate is that the distance d between a substrate S as shown in FIG. 7, more precisely between the surface of substrate S to be coated, and the first sputtering surface 705 and measured along the geometric axis A, should be

0.125 D≦d≦0.5 D,

where D addresses the diameter of a circle which circumcises the first sputtering surface 705 as considered in direction of the geometric axis.

As already shown in FIG. 7, in the space between the first target 703 and the substrate S in the case of a circular target 703 a ring-shaped second magnetron sub-source concentric to the circular shaped first magnetron sub-source is provided. In the today realized form the inner diameter of the concentric, ring-shaped second magnetron sub-source is larger than the diameter of the circular first target. With an eye on FIG. 7 this addresses an embodiment in which on one hand first target 703 is circular about axis A and the second magnetron sub-source 713 is concentric about axis A and thus also ring-shaped, whereby the first target 703 does not overlap the second target 715 of the second magnetron sub-source. As was already addressed, the second sputtering surface 717 can be perpendicular or parallel to the first sputtering surface 705 of the first target 703 or may be, as was already addressed as well, tilted, opening towards the substrate, α as of FIG. 11, so as to enable a better transfer factor and to avoid cross-contamination between the first magnetron sub-source and the second magnetron sub-source. We refer to the embodiments as have been explained in context with the FIGS. 9 to 11.

On the substrate S as of FIG. 7 there is applied Rf bias power, like typically 13.56 MHz in order to generate a bias potential for the acceleration of the generated metal ions as is addressed in FIG. 7 by Rf bias source 723 operationally connected to the substrate S via a substrate holder of the sputtering system as not shown in FIG. 7.

A first setup of a sputtering system according to the invention, making use of a sputtering source arrangement as of the invention and in one of today's practiced modes is shown in FIG. 12. The first target 1203 of the first magnetron sub-source 1201 is operated by pulsed DC power from a power source 1210 as in HIPIMS mode.

The first target 1203 is water-cooled 1241. The first magnet arrangement 1207 is rotated along the back surface 1209 of the first target 1203, as schematically shown by arrow w. A metal frame 1243 is provided all along the periphery of the first target 1203 and is electrically isolated therefrom. Operated on ground potential as shown in this embodiment, the metal frame 1243 acts as an anode with respect to both, the first sputtering sub-source 1201 as well as the second sputtering sub-source 1213.

The second magnetron sub-source 1213 is constructed as schematically shown in FIG. 11. The second target 1215 is electrically isolated from the metal frame 1243.

The second target 1215 is cooled by a water cooling system 1245. The second magnet arrangement 1219 is stationary. The second target 1215 is operated with DC power from DC generator 1247.

In direction along axis A and pointing away from the first sputtering surface 1205, subsequent the second magnetron sub-source 1213, there is provided a further metal frame 1249 which is electrically isolated from the second target 1215 and, operated on ground potential, acts as well as an anode. The substrate S resides on a substrate holder 1251. Via substrate holder 1251 the substrate S is operated on Rf bias power by means of an Rf bias power unit 1253. Metal frame 1255 addresses in fact a remaining part co-defining the reaction space R for sputter-coating between substrate S and the two magnetron sub-sources 1201 and 1213.

Looking back on FIG. 7 there is thus proposed to provide a metal frame (not shown in FIG. 7) between first target 703 and second target 715, isolated from both targets and operated as an anode. Considered in the direction along axis A and pointing away from the sputtering surface 705, there is provided, following the embodiment of FIG. 12, in the embodiment of FIG. 7, a further metal frame between the substrate S and the second target 715, which is as well electrically isolated from second target 715 and operated as an anode. As addressed also in FIG. 7, the substrate S is operated on Rf biasing power.

The first target 703 may thus be operated at pulsed DC power and the second target 715 at DC power. Whereas the first magnet arrangement 707 is moved as was already addressed, the second magnet arrangement 719 may be stationary. Both targets 715 and 703 are cooled by a cooling system, thereby one embodiment each by a separate cooling system, as by a water cooling system.

The first magnetron source 1201 in the embodiment of FIG. 12 as well as the more generic first magnetron sub-source 701 of FIG. 7 are in a today practiced embodiment operated with pulsed DC power, thereby with high peak current and low duty cycle with the intention to generate a high amount of metal ions of the material sputtered off the first magnetron sub-source 1201, 701. This mode of operation is, as was addressed, known as HIPIMS-mode or -process. As was already addressed, on the substrate more generically a bias power is applied, which has to be an Rf bias power in the case the substrate is of electrically insulating material. Thereby, metal ions are accelerated in the vias as of TSVs with the high aspect ratio. In the practiced embodiment as of FIG. 12 the planar-magnetron, first magnetron sub-source 1201 makes use of a rotating magnet arrangement 1207, which has been designed to enable full-surface erosion of the target and generates a uniform metal ion flux as was indicated in context with FIG. 4. The rotating magnet arrangement 1207 is not necessarily designed to generate a uniform deposition on the substrate S under the selected conditions of the target to substrate distance as was addressed above.

The second magnetron sub-source 1213 is run in DC magnetron mode. This is also one possibility to operate the second magnetron sub-source 713 of FIG. 1. Nevertheless, second magnetron sub-source 1213 as of the embodiment of FIG. 12 as well as 713 as of the embodiment of FIG. 7 may be alternatively run in HIPIMS mode.

The limited extension of the second target 1215 in the embodiment of FIG. 12, but as well 715 in the embodiment of FIG. 7, makes it possible to operate the second magnet arrangement 1219 and 719 respectively stationarily, which minimizes complexity and cost of the overall sputtering source arrangement. If the second magnet arrangement 1219 as of FIGS. 12 and 719 as of FIG. 1 shall be conceived as moving magnet arrangement, this may e.g. be realized by providing the magnet 1257 and an analogy magnets of magnet arrangement 719 to be movable on one hand up and down in planes according to plane E₂ of FIG. 7 and additionally in azimuthal direction, i.e. along the loop of the respective second target, as addressed schematically in FIG. 12 by the direction a. This results in a snake-like, wobbling movement of the respective magnets 1257 along the second sputtering surface 1217 as of FIG. 12 or 717 as of FIG. 7 from one looping edge of the second sputtering surface to the other looping edge thereof. Such a drivingly moved second magnet arrangement 1219′ is shown in the embodiment of FIG. 13, which, besides of the movable second magnet arrangement 1219′, is identical to the embodiment of FIG. 12.

As was already addressed, in one embodiment the second target 715 as of FIG. 7 and 1215 as of FIG. 12 has its own water-cooling circuit 1245 shown in FIG. 12, which is able to cool several kW of sputtering power. The first magnetron sub-source 1201, 701 is operated with pulsed DC power, thereby one embodiment with HIPIMS power, while the second magnetron sub-source 1213 and accordingly 713 is operated by a standard DC power supply.

The embodiment as schematically shown in FIG. 14 is the same as that of FIG. 12 with the exception that no metal frame as of 1243 is provided as an anode frame between the first magnetron sub-source 1201 and the second magnetron sub-source 1213.

The embodiment of FIG. 14 may be a good embodiment in applications, where space is limited.

According to this embodiment, the second target 1415 is extended by the metal frame part 1443, with an eye on the embodiment of FIG. 12. Apart from this difference to the embodiment of FIG. 12, the two embodiments of FIG. 12 and FIG. 14 are equal. The second target 1415 together with the metal frame 1443 electrically connected to the second target 1415 or even made of one metal piece is operated as an anode whenever the first sputtering sub-source 1401 is operated. The second target 1415 combined with the metal frame part 1443 is almost exclusively only sputtered off there, where the second magnet arrangement 1419 is located and thus along the target part 1415.

Addressing the timespan during which the first sputtering source 1401 is sputter-operated as T₁ and the timespan during which the second magnetron sub-source 1413 is sputter-operated as T₂, this embodiment is especially suited, where the two timespans T₁ and T₂ do not overlap. Nevertheless, it might be possible to exploit the DC operated parts 1415 and 1443 as anode also when T₁ and T₂ do overlap. On a respective DC power level the second target 1415 and especially the metal frame part 1443 may also then act as an anode for sputter-operation of the first magnetron sub-source 1401, especially when operated in HIPIMS mode.

During timespans out of T₂, in which only the second magnetron sub-source 1413 is operated, on one hand metal frame 1449 acts as an anode. Additionally the first target 1403 may then be operated so as to act as an anode for the second magnetron sub-source 1413.

The embodiment of FIG. 15 accords with the embodiment of FIG. 12, whereby instead of a metal frame 1243 as of the embodiment of FIG. 12, exploited as a grounded anode, a metal frame 1543 is operated at electrically floating potential. Thus, a floating ring spacer 1543 is realized between the first magnetron sub-source 1501 and the second magnetron sub-source 1513. This may have the advantage that during pulsed sputtering the electrons have to find their way to a more remote anode, namely metal frame anode 1549 and possibly target 1515 of the second magnetron sub-source 1513. As a consequence the ions are more thoroughly extracted to the plasma volume and there may be achieved an even better via filling.

All the special features which have been described, especially with respect to the FIGS. 12 to 15, may be realized separately or in any combination, if they are not in contradiction, in a more generic embodiment as has been addressed and exemplified by means of FIG. 7.

Now the operating mode of the sputtering source arrangement and sputtering system according to the invention and operating the manufacturing method shall be addressed more in details. As has been addressed up to now especially with an eye on the FIGS. 12 to 15, the first and the second magnetron sub-sources have both an individual power supply. The first magnetron sub-source is operated in pulsed DC mode, thereby especially with very high current pulses at a low duty cycle, also called HIPIMS mode.

For a planar first target with a diameter of 400 m there is proposed to apply a pulse length of between 100 μsec and 200 μsec. The current pulses should be allowed to reach the maximum in approx. 100 μsec, which maximum should be in the range between 600 and 1000 A. The duty cycle should typically be in the range of 5 to 15%. If the target size differs from a 400 mm diameter circular shape, which accords with a surface of 2240 cm², the respective parameters should be adapted to the prevailing surface extent so, that assumed the target surface was that of the 400 mm circular target, the addressed parameter values would be fulfilled.

The coating process, especially for coating plate-shaped substrates of electrically isolating materials having vias along the metal-coated plate surface and thereby especially when such vias have an aspect ratio of at least 10:1, is run in at least two steps. In a first step the first magnetron sub-source is operated in HIPIMS mode, in a second step the second sputtering sub-source is operated.

A first timespan T₁ defines the operating timespan of the first step, sputter-operating the first magnetron sub-source, a second timespan T₂ defines the extent of the second step, sputter-operating the second magnetron sub-source. The timespans T₁, T₂ may be of respectively desired length and may be staggered in time according to the specific application. Thus and according to FIG. 16 the two timespans T₁ and T₂ may be of identical extent. Then T₁ and T₂ may be established simultaneously, FIG. 16(a) or, FIG. 16(b), T₂ may be started after the start and before the end of timespan T₁ or, according to FIG. 16(c), T₂ may be started at or after the end of T₁ or

FIG. 16(d), T₁ may be started after starting and before the end of T₂, or

FIG. 16(e), T₁ may be started at or after the end of T₂.

FIG. 17 shows the possible time relations of T₁ and T₂ if T₁ is longer than T₂.

In analogy FIG. 18 shows the possible time staggering of T₂ and T₁, when T₂ is longer than T₁. It is felt that no additional comment is necessary for the skilled artisan to understand FIGS. 17 and 18.

During step 1 of time extent T₁ the first magnetron sub-source as of 701 of FIG. 7 is operated in HIPIMS mode with an average power of P₁. In the second step of a duration T₂ the second magnetron sub-source, as of sub-source 713 in FIG. 7, is operated in DC magnetron mode with a power of P₂. Step 1 of T₁ is used to get a maximum amount of ionized material into the vias, while step 2 with an extent of T₂ is used to adjust the film to a uniform thickness. Both steps are run with Rf bias power application to the substrate.

The advantages of the addressed two-step processing are:
a) a still small target size of the first magnetron sub-source can be used, even in situations with an increased target to substrate distance (medium throw)
b) since by the HIPIMS process there is usually more material in the via towards the substrate edge, the uniformity in the via and along the extended substrate surface can be balanced.
c) The second magnetron sub-source can be used very elegantly to adjust the upcoming effects over target life by mutually adjusting the timespans T₁ and T₂.
d) While for the pulsed mode of step 1, the Rf bias accelerates the metal ions into vias, the continuous mode in step 2, run by the second magnetron sub-source, generates predominantly ions of a working gas, as of Ar, which can be used to back-sputter overhanging material on the edges of the vias.

By adjusting the ratio of the step times T₁ and T₂ the layer uniformity on the substrate can be adjusted. By controlling the ion Rf bias power, especially in the step 2, the amount of back sputtering can be adjusted to remove overhanging edges in the via opening. Since when operating the first magnetron sputtering sub-source during step T₁ in HIPIMS high peak currents have to be achieved, usually a high process pressure is then preferred. In contrary, back sputtering process in step 2 is preferably run at a lower pressure, which can easily be established for DC magnetron sputtering.

In one embodiment, the first magnetron sub-source and the second magnetron sub-source can be used in combination and operated by one bipolar power supply 1940 as schematically shown in FIG. 19, operating both the first target 703 and the second target 715 as of FIG. 7.

This kind of bipolar power supply 1940 can be manufactured as a H-bridge and is available on the market. During step 1 the bipolar source 1940 is run in unipolar pulsed DC mode with a negative pole on the first target 703 and at an average power of P₁—or at a voltage set point V1—for the timespan T₁, followed by step 2 with a timespan T₂ where the second target 715 is run in unipolar DC mode with a negative pole on target 715 at a different voltage or power set point P₂ as shown in FIG. 20. Alternatively, with a bipolar power supply 1940 step 2 can also be run in HIPIMS mode with reversed polarity.

Further, step 1 and step 2 can be run e.g. alternating several times. This can be advantageous if step 1 produces an overhanging edge in the via opening, which prevents further filling of the via, so that some intermittent back sputtering is necessary.

### Example 1

A sputtering source arrangement with a planar circular first magnetron sub-source is used with a target diameter of 400 mm. The target to substrate distance TSD is 140 mm. The substrate has a diameter of 300 mm. The ring-shaped second magnetron sub-source has a second target which, according to the embodiment of FIG. 11, has a α=45° slope, an inner radius of 200 mm and an outer radius of 215 mm and is arranged between the target of the first magnetron sub-source and the substrate. FIG. 21 shows the erosion profile of the first target, whereas FIG. 22 shows the erosion profile of the second target.

The deposition uniformity has been calculated for a target to substrate distance TSD_R varying between 30 and 130 mm. For each individual radius from 0.0 to 150.0 mm on the substrate, the deposition contribution of the first magnetron sub-source dₚₛ (r) and of the second magnetron sub-source dᵣₛ (r) can be superimposed to a resulting thickness dₜₒₜₐₗ (r). The deposition profile dₜₒₜₐₗ (r) can thus be optimized by a mixing factor F of the first and the second magnetron sub-sources:

dₜₒₜₐₗ(r)=dₚₛ(r)+F*dᵣₛ(r) (1)

Table 1 shows the calculated deposition profile together with the superposition factor F for the second magnetron sub-source source at different TSD_R. The uniformity profile is plotted in FIG. 23, which shows the uniformity profile optimized by different ratios of second magnetron sub-source contribution relative to first magnetron sub-source contribution for TSD_R varying between 30 mm and 130 mm and as of example 1.

FIG. 24 shows the relative contribution of the second magnetron sub-source, to adjust the uniformity, for TSD_R varying between 30 mm and 130 mm for the optimized deposition profile. Depending on the position of the second magnetron sub-source and the radius on the substrate, the relative contribution of the second magnetron sub-source is varying between 10% and 70%.

FIG. 24 as addressed shows the relative contribution of the second magnetron sub-source to the total film thickness to adjust the uniformity for TSD_R varying between 30 mm and 130 mm for the optimized deposition profile as shown in FIG. 23.

The calculation above has been performed with a so-called cosine emission profile. As it is well-known to the skilled artisan, the sputter emission profile can be described by

I=[cos(∂)+C(2 cos(∂)−3 cos²(∂))]/π (2)

FIG. 25 shows the modelled emission profile typically used in sputtering simulations with C varying from −1, the so-called butterfly profile, to C=1, already a slightly directional profile, in a polar diagram. A majority of the materials show an emission profile with C=0, called the cosine emission profile. Now it may be argued that the second magnetron sub-source can be sensitive to the nature of the sputter emission profile, especially for a short distance between the addressed second magnetron sub-source and the target of the first magnetron sub-source.

Therefore, the simulation has been repeated for a TSD_R of 30 mm and emission profiles with C between −1 and +1. The deposition uniformity profile is plotted in FIG. 26 and shows a very small effect of C varying between −1 and +1. FIG. 26 shows the uniformity profile for the closest TST_R of 30 mm for target material emission characteristic between −1 and +1 as of example 1.

FIG. 27 shows the relative contribution of the second magnetron sub-source to adjust the uniformity for the closest TSD_R of 30 mm and for target material emission characteristics between −1 and +1.

Example 1 has shown that the superposition factor F for the second magnetron ring source seems to be quite high. The reason for this is a narrow erosion profile of the second magnetron sub-source of only approx. 18 mm, which bears the risk of a quite limited target life in relation to the target life of the first magnetron sub-source, which is a planar source.

Example 2 now uses the same first magnetron sub-source, a planar source with a target diameter of 400 mm and erosion profile as plotted in FIG. 21. The TSD_R is also 140 mm. However, in this example the second target of the second magnetron sub-source is tilted α=55° against the substrate and the erosion track has an inner radius of 210 mm and an outer radius of 248 mm as shown in FIG. 28. Thereby, the target with α=55° angle between sputtering surface and with a radius of 216 and 255 mm is used. Projected on the

surface of the ring target of the second magnetron sub-source, the erosion profile is approx. 46 mm. A wide erosion profile can usually be either achieved by moving magnets or by a magnet yoke design, which provides a flat magnetic field on the sputtering surface, therefore resulting in a wide erosion profile.

In Table 2 the calculated uniformity profile is listed for TSD_R varying between 60 mm and 100 mm as optimized by different superposition factors F for the second magnetron sub-source. FIG. 29 shows the uniformity profiles optimized by superposition of effects of the second magnetron sub-source and the first magnetron sub-source for TSD_R between 60 mm and 100 mm. In FIG. 30 the relative contribution of the second magnetron sub-source to the total film thickness on the substrate to adjust to the best uniformity is shown. The calculated uniformity and superposition factor for the Example 2 versus TSD_R are plotted in FIG. 31.

What is claimed is:

1. A sputtering source arrangement comprising
A second magnetron sub-source with a close-frame shaped second target of said material and along the periphery of and electrically isolated from said first target, said second target having a second sputtering surface arranged around said geometric axis, a second magnet arrangement along and adjacent a back-surface of said second target, so as to establish a second magnetron magnetic field along said second sputtering surface.
Around a geometric axis, a first magnetron sub-source with a first target of a material having a first sputtering surface defining a plane perpendicular to said geometric axis and comprising a first magnet arrangement adjacent a back surface of said first target, drivingly movable along said first sputtering surface so as to establish a moving close loop first magnetron magnetic field, movable along said first sputtering surface;

2. The sputtering source arrangement of claim 1, wherein said first target is at least one of plane and of circular.

3. The sputtering source arrangement of claim 1, wherein said second sputtering surface defines, in a cross-sectional planes containing said geometric axis, a pair of substantially straight lines.

4. The sputtering source arrangement of claim 1, wherein said second sputtering surface defines around said geometric axis, a surface one of parallel to said geometric axis, perpendicular to said geometric axis and thereby, preferably, facing away from said first sputtering surface, and of cone shaped, opening in a direction along said geometric axis and pointing away from said first sputtering surface.

5. The sputtering source arrangement of claim 1, comprising a metal frame between said first sputtering surface and said second sputtering surface, extending along said periphery of said first sputtering surface and along said second sputtering surface, said metal frame being one of:
operable as an anode and electrically isolated from said first and from said second targets;
operable electrically on a floating potential and electrically isolated from said first and from said second targets;
electrically connectable to said second target.

6. The sputtering source arrangement of claim 1, comprising a frame shaped anode, arranged, in a direction along said geometric axis and away from said first sputtering surface, subsequent to, adjacent to and along said second sputtering surface.

7. The sputtering source arrangement of claim 1, said second magnet arrangement comprising a frame of magnets along said back-surface of said second target, the magnetic dipoles of said magnets being arranged in sectional planes containing said geometric axis.

8. The sputtering source arrangement of claim 1, said second magnet arrangement being one of stationary with respect to said second sputtering surface and of drivingly movable with respect to said second sputtering surface, preferably in directions in sectional planes containing said geometric axis as well as along said second sputtering surface in azimuthal direction with respect to said geometric axis.

9. The sputtering source arrangement of claim 1, comprising a cooling system including a pipe system for a cooling medium along said first and along said second targets, preferably comprising a first cooling subsystem for said first target and a second cooling subsystem for said second target.

10. A sputtering system comprising a sputtering source arrangement of claim 1, and a power source arrangement operationally connectable to said first and to said second magnetron sub-sources and constructed to operate said first sub-source in a first mode being a pulsed DC mode and said second sub-source in a second mode.

11. The sputtering system of claim 10, wherein said pulsed DC mode is a HIPIMS mode.

12. The sputtering system of claim 11, wherein said power source arrangement operates said first target as follows:
Adapted to a prevailing extent of said first sputtering surface so, that for an assumed extent of said first sputtering surface of 2240 cm² there is then valid:
Peak of current pulses: 600 to 1000 A
Length of current pulses: 100 μsec to 200 μsec
Duty cycle, i.e. pulse ON- to pulse OFF-time ratio: 5% to 15%.

13. The sputtering system of claim 10, said second mode being a DC mode or a further pulsed DC mode.

14. The sputtering system of claim 10, said second mode being a HIPIMS mode.

15. The sputtering system of claim 10, wherein said power source arrangement is time controllable so as to establish said first mode during a first time span and said second mode during a second time span, whereby, preferably, said time spans are adjustable.

16. The sputtering system of claim 15, wherein said second time span is started after start of said first time span.

17. The sputtering system of claim 15, wherein said first and second time spans do not overlap.

18. The sputtering system of claim 17, said time controlled power source arrangement operating at least one of said second target as an anode when said first mode is enabled and of said first target as an anode when said second mode is operated.

19. The sputtering system of claim 10, wherein one of said first and second targets is operated as an anode during a time span the other of said first and second targets is operated as a cathode and vice versa.

20. The sputtering system of claim 10, wherein said power source arrangement comprises a first power source operationally connected to said first target and a second power source operationally connected to said second target.

21. The sputtering system of claim 10, further comprising a substrate holder for a plate shaped substrate, said substrate holder being constructed to hold a plate shaped substrate in a plane perpendicular to said geometric axis, a surface of said substrate held in said substrate holder and to be sputter coated facing said first and second targets.

22. The sputtering system of claim 21, comprising a biasing power source, preferably a Rf biasing power source, operationally connectable to said substrate holder and preferably generating a first Rf power level when said first magnetron sub-source is sputter-operated and a second, different Rf power level, when said second sputter sub-source is sputter operated.

23. The sputtering system of claim 21, wherein said substrate holder is constructed to establish a distance d along said geometric axis between said first sputtering surface and a surface of a plate shaped substrate on said substrate holder to be sputter coated, and with respect to a diameter D of a circle circumscribing said first sputtering surface, considered in a direction along said geometric axis, so that there is valid:
0.125 D≦d≦0.5 D.

24. The sputtering system of claim 21, wherein said first sputtering surface overlaps the periphery of a plate shaped substrate on said substrate holder.

25. The sputtering system of claim 21, wherein, considered in a direction along said geometric axis, said second target is arranged subsequent said first target and a substrate which is held by said substrate holder is arranged subsequent said second target.

26. A method of manufacturing metal coated, plate shaped substrates of electrically isolating material, having vias along the metal coated plate surface, said vias being as well metal coated, comprising coating plate shaped substrates of electrically isolating material having vias along at least one of the plate surfaces by means of a sputtering system according to claim 10.

27. The method of claim 26, said vias having, before being coated, an aspect ratio of at least 10:1.

28. The method of claim 26, comprising:
providing a plate shaped substrate with vias perpendicularly to said geometric axis, said vias facing said first sputtering surface,
first magnetron sputter coating said substrate with a metal by means of said first sputtering surface, thereby operating said first target in a HIPIMS mode and drivingly moving said first magnet arrangement along said first sputtering surface;
Second magnetron sputter coating said substrate with said metal by means of said second sputtering surface.

29. The method of claim 28, comprising establishing said first sputter coating during a first timespan T₁, establishing said second sputter coating during a second timespan T₂ and selecting said time spans in one of the following modes:
T₁ is of equal extent as T₂ and one of the following prevails:
T₁ is established simultaneously with T₂
T₂ is started after the start and before the end of T₁
T₂ is started at or after the end of T₁
T₁ is started after starting and before the end of T₂
T₁ is started at or after the end of T₂
T₁ is of longer extent than T₂ and one of the following prevails:
T₂ is within T₁
at least a part of T₂ is subsequent the end of T₁
at least a part of T₁ is subsequent the end of T₂
T₂ is of longer extent than T₁ and one of the following prevails:
T₁ is within T₂
at least a part of T₁ is subsequent the end of T₂
at least a part of T₂ is subsequent the end of T₁
whereby, preferably T₂ starts at or after the end of T₁.

30. The method of claim 29, thereby sputter operating at least one of said first target during said first timespan T₁ and of said second target during said second timespan T₂ more than one time.

31. The method of claim 26, wherein said second target is operated by one of DC mode, pulsed DC mode, HIPIMS mode.

32. The method of claim 26, wherein said first and said second targets are operated by an output-controllable common power source.

33. The method of claim 32, said common power source being operationally interconnected between said first and said second targets.

34. The method of claim 33, said common power source arrangement operating said first target in HIPIMS mode, said second target in one of DC mode, pulsed DC mode and HIPIMS mode.

35. The method of claim 34, said common power source operating said second target in pulsed DC or in HIPIMS mode thereby inverting pulse polarity when changing from sputter-operating said first target to sputter-operating said second target.

36. The method of claim 26, wherein at least one prevails:
said second sputtering surface is exploited as a first anode surface during a time span said first sputtering surface is sputtered;
said first sputtering surface is exploited as a second anode surface, during a time span said second sputtering surface is sputtered.

37. The method of claim 26, thereby applying during sputter-operating said first and said second targets Rf bias power to said substrate, preferably a first Rf power level when sputter operating said first target and a second different Rf power level when sputter-operating said second target.

38. The method of claim 29, when depending on claim 29, thereby adjusting the thickness-distribution of material deposited on said plate surface and along said plate surface by adjusting the ratio of said first and of said second time spans.

39. The method of claim 38, thereby performing said adjusting said thickness distribution during target life.
